(19) United States
(12) Patent Application Publication
(10) Pub. No.: US 2013/0113499 A1
(43) Pub. Date: May 9, 2013

(54) METHOD AND APPARATUS FOR DETERMINING PLANAR IMPEDANCE TOMOGRAPHY

(71) Applicants: Michael C. Golt, North East, MD (US); Matthew S. Bratcher, Baldwin, MD (US); Todd L. Jessen, Middle River, MD (US)

(72) Inventors: Michael C. Golt, North East, MD (US); Matthew S. Bratcher, Baldwin, MD (US); Todd L. Jessen, Middle River, MD (US)

(73) Assignee: U.S. Government as represented by the Secretary of the Army, Adelphi, MD (US)

(21) Appl. No.: 13/461,072

(22) Filed: May 1, 2012

Related U.S. Application Data
(60) Provisional application No. 61/556,894, filed on Nov. 8, 2011.

(51) Int. Cl. G01R 27/00

(52) U.S. Cl. 324/600

(57) ABSTRACT

A method and apparatus for determining planar impedance tomography of a sample comprising a measurement head unit comprising an impedance sensor; a three-axis actuator assembly, coupled to the measurement head unit, for positioning the impedance sensor relative to a sample; a controller, coupled to the three-axis actuator assembly, for controlling the three-axis actuator assembly to position the impedance sensor at a plurality of locations relative to the sample; and an impedance analyzer, coupled to the impedance sensor, for determining an impedance value at each location in the plurality of locations.

### REFERENCE TO CO-PENDING AND ISSUED PATENTS

This application claims priority from U.S. provisional patent application No. 61/556,894, filed on 8 Nov. 2011. The entire disclosure of which is incorporated herein by reference.

### GOVERNMENT INTEREST

Governmental Interest—The invention described herein may be manufactured, used and licensed by or for the U.S. Government.

### FIELD OF USE

Embodiments of the present invention generally relate to impedance measurement techniques and, more particularly, to a method and apparatus for determining planar impedance tomography.

### BACKGROUND

The electrical impedance of a material is a measure of its resistance to the flow of an alternating electric current. From a complex vector measurement of the impedance, the basic electrical characteristics of the material such as its Resistance R, and frequency dependent properties such as the Inductance L and Capacitance C can be derived. Generally, a material's structure and chemical composition define its impedance to alternating electric current. Therefore, the material's physical and chemical structure can be represented in terms of basic circuit elements of R, L, and C. The impedance of materials is routinely measured by placing the sample between two parallel electrodes, applying an alternating voltage potential to the electrodes, and measuring the electrical current that flows through the sample. The measured impedance is then typically represented in the form of capacitance (C), in which the material property known as the dielectric constant is calculated via Equation 1.

$${ɛ}_{r} = \frac{Cd}{{ɛ}_{0} A} \qquad ( 1 )$$

Herein the dielectric constant is computed by measuring the capacitance (C) of a material and knowing the separation distance (d) and area (A) of parallel plate measurement electrodes. The permittivity of free space, ε₀=8.854E-12 F/m. The dielectric constant of a material is frequency dependent and represents its ability to store electrical energy. There is a time-varying electric field that is created when an alternating voltage potential is placed across the measurement electrodes. This changing electric field causes the various electrical dipoles within a material to change their polarization with time. The greater this polarization, the greater the amount of electrical energy can be stored, which means the higher the material's dielectric constant. The ease at which this change in polarization occurs is measured by the complex component of the impedance, the Reactance X, and is related to how out of phase the polarization is with the changing electric field. The Quality Factor Q is typically used to represent the quality of the reactance, and is the ratio between the stored energy and energy lost in polarizing the material. Materials with low dielectric constants, generally have a high Q, and are therefore good electrical insulators as they store little electrical energy. High dielectric materials typically have lower Q because the larger polarizations usually dissipate more energy when they are created.

As previously stated, impedance can also be converted to the frequency dependent property of inductance. An inductor is analogous to a capacitor in that it stores energy; however, inductors store their energy in a magnetic field as opposed to an electric field. The Inductance L of a material is its ability to store this energy. When electrical current flows through a wire it generates a magnetic field. If the wire is coiled this field is magnified, as such typical inductors are composed of a number of turns of wire around a core. The inductance is tuned by the number of turns of the wire forming the coil, the radius of the coil, and the composition of the core. If an alternating current is applied to the coil, an alternating magnetic field is also produced. This changing magnetic field in turn produces its own electrical current that opposes the initial magnetic field generating current. There are two primary forms of inductance; self-inductance which occurs within a single inductor and mutual inductance in which one inductor's changing magnetic field induces an alternating current in another inductor. If an inductor is placed within close proximity to a conductive material, the alternating magnetic field from the inductor will generate circulating currents within the material, known as eddy currents. These eddy currents in turn generate their own magnetic fields that affect the inductor as a change in its inductance. Defects in the conductive material alter the eddy current's magnetic field, and as a result a change in the mutual inductance between the material and the inductor. The field of eddy current testing is a non-destructive evaluation technique based upon measuring the change in the induced eddy currents of conducting samples.

Typically, a material's dielectric constant is measured within a laboratory-scale test fixture consisting of two parallel plates, one fixed, and the other attached to a micrometer that allows measurable movement up and down. A material sample is sandwiched between the two plates and a sample thickness is measured using the micrometer. This thickness along with the measured capacitance is used to calculate the dielectric constant of the material using. Equation 1. Depending upon the equipment involved, this technique is capable of measuring the dielectric constant of materials spanning a wide impedance range. However, the limitations with this approach are twofold: (1) the sample must be thin (e.g., less than one inch) for known commercially available test fixtures, and (2) only a small subsection of the sample can fit within the test fixture. Therefore, when measuring the dielectric constant of large objects the assumption must be made that a small subsection represents the entire object. For most non-destructive material evaluation scenarios, this assumption cannot be relied upon.

The next common alternative to measuring the dielectric constant of a material that is sample independent measures an interaction between the sample and a radiofrequency (RF) traveling electromagnetic wave. In this approach, a sample is placed proximate a conductor on a two-axis stage. A lens-focused electromagnetic wave travels through the sample and reflects from a conductor and travels back through the material on its way to a detector. By rastering the sample through the focused electromagnetic wave, a reflection coefficient is measured and the dielectric constant of the material can be calculated at discrete locations on the sample. This technique only works with material samples that minimally attenuate the electromagnetic wave, such as good insulators. Thus, the free-space approach accommodates large sample sizes, yet it is impedance-limited.

Therefore, there is a need in the art for an improved method and apparatus for measuring planar impedance tomography of large samples.

### BRIEF SUMMARY

Embodiments of the present invention comprise an apparatus for determining planar impedance tomography of a sample comprising a measurement head unit comprising an impedance sensor; a three-axis actuator assembly, coupled to the measurement head unit, for positioning the impedance sensor relative to a sample; a controller, coupled to the three-axis actuator assembly, for controlling the three-axis actuator assembly to position the impedance sensor at a plurality of locations relative to the sample; and an impedance analyzer, coupled to the impedance sensor, for determining an impedance value at each location in the plurality of locations.

Another embodiment of the present invention comprises a computer implemented method of measuring a planar impedance tomography of a sample comprising a scan defining a plurality of locations upon a sample; positioning an impedance sensor at a first location in the plurality of locations; measuring an impedance value using the impedance sensor at the first location; storing the impedance value from the first location; positioning the impedance sensor at least one additional location in the plurality of locations; measuring an impedance value using the impedance sensor at the at least one additional locations; and storing the impedance values from at least one additional locations.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a block diagram representing an apparatus for measuring planar impedance tomography in accordance with at least one embodiment of the invention;

FIG. 2 depicts a perspective view of a measurement head unit used in the apparatus of FIG. 1 in accordance with at least one embodiment of the invention;

FIG. 3 depicts a cross-sectional representation of a capacitance-based measurement head unit that may be used as a portion of the apparatus of FIG. 1 in accordance with at least one embodiment of the invention;

FIG. 4 depicts a cross-sectional representation of an inductance-based measurement head unit that may be used as a portion of the apparatus of FIG. 1 in accordance with at least one embodiment of the invention;

FIG. 5 depicts the impedance sensor of the apparatus of FIG. 1 being used in a contact mode in accordance with at least one embodiment of the invention;

FIG. 6 depicts the impedance sensor of the apparatus of FIG. 1 being used in a non-contact (hover) mode in accordance with at least one embodiment of the invention;

FIG. 7 depicts a flow diagram representing a method of operation for the apparatus of FIG. 1 in accordance with at least one embodiment of the invention.

### DETAILED DESCRIPTION

Embodiments of the present invention comprise a method and apparatus for measuring planar impedance tomography of materials. The embodiments comprise a three-axis actuator assembly for positioning a measurement head unit (MHU) proximate to a planar material sample (where the planar material sample may not have a uniform surface). The MHU comprises one or more interchangeable impedance sensors (e.g., capacitive-based sensor, inductance-based sensor, resistance-based sensor, radio frequency-based sensor and the like). More specifically, the MHU comprises an impedance sensor coupled to force-feedback sensor via a resilient (compressible) joint. As such, the impedance sensor is capable of articulation about a vertical axis (i.e., relative to the actuator assembly) to enable positioning the sensor to measure impedance of non-uniform surfaces as well as sense obstructions when the actuator assembly moves the impedance sensor.

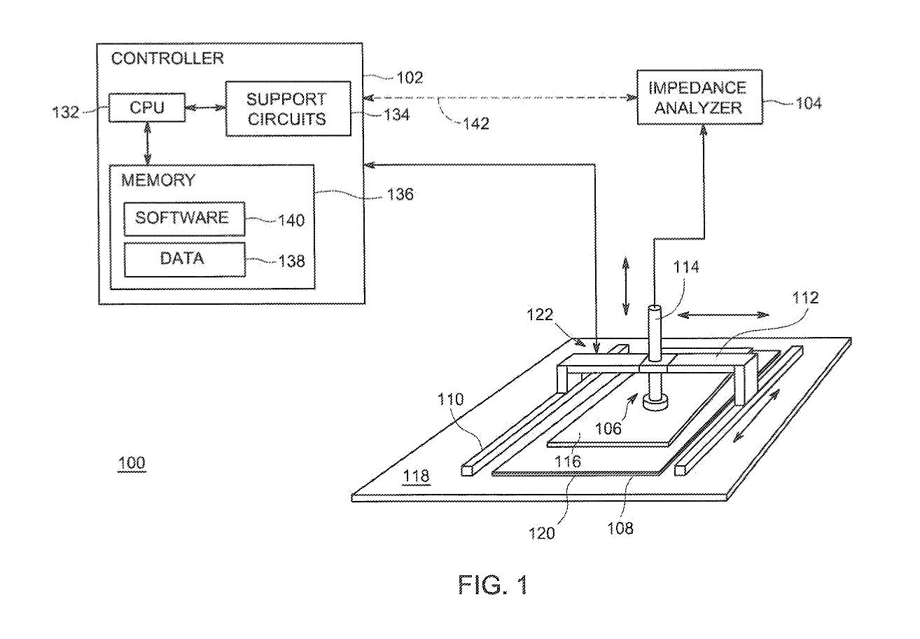

FIG. 1 depicts a block diagram representing an apparatus 100 for measuring planar impedance tomography of a sample 116 in accordance with at least one embodiment of the invention. The apparatus 100 comprises a controller 102, impedance analyzer 104, three-axis actuator assembly 122, a measurement head unit (MHU) 106, and a fixed electrode (bottom electrode) 108. The three-axis actuator assembly 122 comprises an X, Y, and Z-dimension actuators 110, 112, 114 arranged to position the MHU 106 relative to the fixed electrode 108. Each actuator 110, 112, 114 may comprise, for example, a linear actuator such as a screw drive, a ball screw drive, a linear belt drive, or a combination thereof. Those skilled in the art will recognize that any form of three-dimensional actuator assembly 122 may be used to position the measurement head unit 106 relative to the sample 116. As described below, the controller 102 controls the MHU 106 positioning.

To determine a planar impedance tomography of a material sample 116, the sample 116 is positioned within the span of the three-axis actuators 110, 112, 114. In one embodiment, the fixed electrode 108 has dimensions that are not less than the dimensions of the sample 116. In other embodiments, the fixed electrode 108 has dimensions that are not less than the region of the sample 116 wherein impedance measurements are to be made. In one embodiment, the fixed electrode 108 is electrically isolated from a table surface 118 via an electrically insulating material 120.

The controller 102, through execution of software instructions, generates a measurement path for the MHU 106 and sends motion commands to the 3-axis actuator assembly 122 to position the MHU 106 relative to the sample 116, i.e., the controller defines a scan for accumulating impedance values at a plurality of locations on the sample 116. Once the MHU 106 has been positioned at a measurement location, the Z-axis actuator 114 (vertical) lowers the MHU 106 to either contact a surface of the sample 116, or to a set distance above the surface of the sample 116.

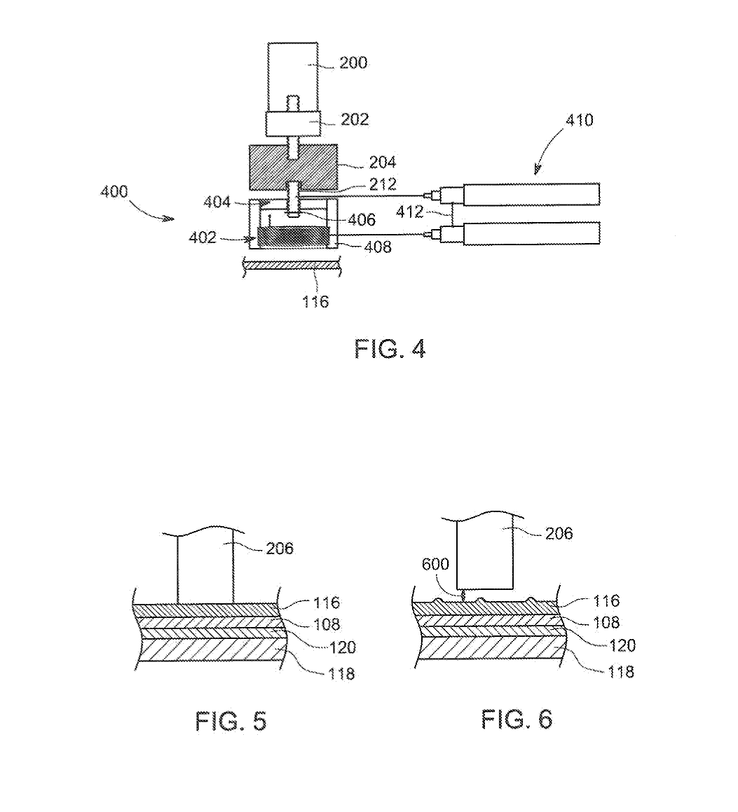

One embodiment of the controller 102 comprises a central processing unit (CPU or simply referred to as a processor) 132, support circuits 134 and memory 136. The CPU 132 may comprise one or more processors, microprocessors, microcontrollers and combinations thereof configured to execute non-transient software instructions to perform various tasks in accordance with the present invention. The support circuits 134 comprise well-known circuits that facilitate operation of the CPU 132 including, but not limited to, clock circuits, busses, network interfaces, input output circuits, cache, power supplies, and the like. The memory 136 comprises random access memory, read only memory, or combinations thereof. The memory 136 stores data 138 and non-transient software 140. In one embodiment, the software 140 comprises control software including instructions that cause a general purpose computer to operate as a specific purpose computer, e.g., the controller 102. In one embodiment, the software 140, in addition to controlling the positioning of the MHU 106, may receive impedance values (data 138) via path 142 from the impedance analyzer 104. The controller 102 may analyze and/or display the impedance values as a impedance tomography (e.g., impedance values versus location). In other embodiments, the impedance values may be stored, processed, analyzed or displayed using a remote computer (not shown). The operation of the apparatus 100 upon execution of the software 140 is described with respect to FIG. 4 below.

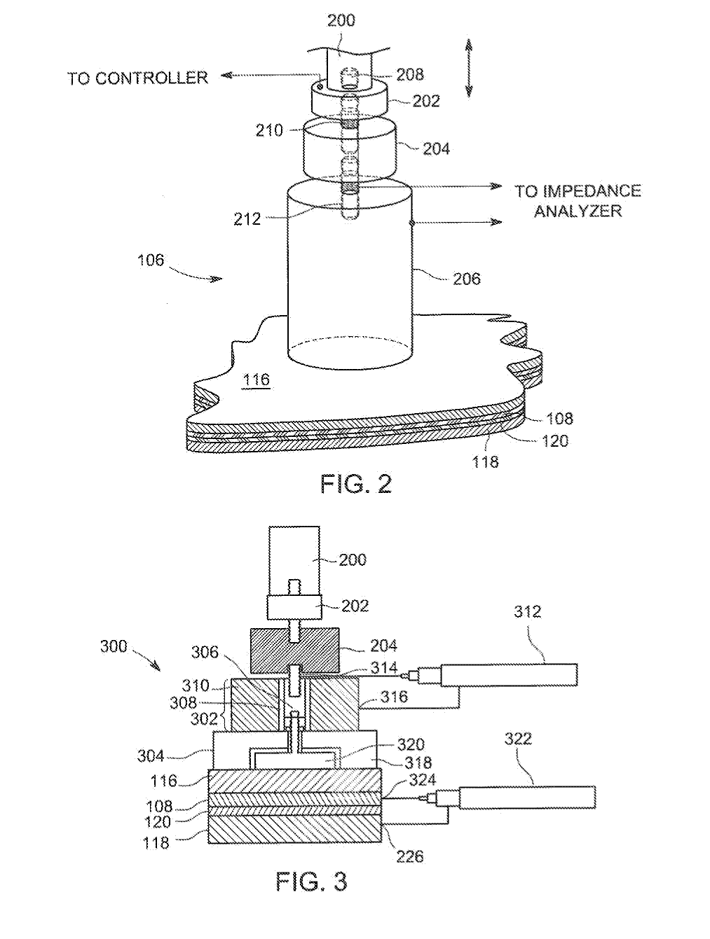

FIG. 2 depicts a perspective view of the MHU 106 used in the apparatus 100 of FIG. 1 in accordance with at least one embodiment of the invention. The MHU 106 comprises a support 200, a force-feedback sensor 202, a compressible joint 204 and an impedance sensor 206. The force feedback sensor 202 is coupled to the support 200 via, for example, press fit, threaded stub, adhesive, and the like. As one example, FIG. 2 depicts a threaded stud 208. The compressive joint 204 is vertically aligned with the force feedback sensor 202 and coupled to the sensor 202 via, for example, press fit, threaded stub, adhesive, and the like. As one example, FIG. 2 depicts a threaded stud 210. The impedance sensor 206 is coupled to the compressive joint 204 via, for example, press fit, threaded stub, adhesive, and the like. As one example, FIG. 2 depicts a threaded stud 212.

In one embodiment, the comprehensible joint 204 is a resilient electrically insolating material providing an ability for the impedance sensor 206 to articulate relative to the support 200 and the sample 116. The articulation enables the sensor 206 to contact and measure the impedance of materials having non-uniform surface textures. The electrical insulating properties of the joint 204 reduces electrical noise coupled to the sensor 206 and ensures electric signals used by sensor 206 are not coupled to the actuator assembly 122 of FIG. 1.

The force feedback sensor 202 generates a signal that is coupled to the controller. The signal represents the amount of vertical force applied to the sensor 202. This signal may be used to: (1) determine when the sensor 206 contacts a sample 116, (2) determine a specific force between the sensor 206 and the sample 116, or (3) determine when a sensor 206 impacts a non-uniform portion of the sample during horizontal positioning of the MHU 106.

If contact with the sample surface is desired, the force-feedback sensor 202 measures the amount of load the impedance sensor 206 places on the sample 116. The Z-axis actuator (114 of FIG. 1) lowers the MHU 106 until an operator (or software)-defined load value is reached. At the point at which the 3-axis actuator has placed the MHU 106 into at the desired two-dimensional planar location and the Z-axis actuator has placed MHU 106 at the desired vertical location relative to the sample surface, an impedance measurement is ready to be taken. The controller initiates a measurement by sending a command to the impedance analyzer to perform a measurement. The technique used to measure the impedance of the sample is dependent on the type of impedance sensor 206. (e.g., capacitive-based sensor, inductance-based sensor, resistance-based sensor, RF reflection sensor and the like). Specific embodiments of the sensor 206 are described with respect to FIGS. 3 and 4 below. The impedance sensor 206 is interchangeable via the threaded stud 212 such that a plurality of sensor types may be used. The embodiment shown in FIG. 2 utilizes a single impedance sensor 206; however, in other embodiments, the MHU 106 may comprise a plurality of different types of impedance sensors.

FIG. 3 depicts a cross-sectional representation of a capacitance-based impedance sensor 300 that may be used as a portion of the apparatus of FIG. 1 in accordance with at least one embodiment of the invention. The sensor 300 comprises an electrode adaptor 302 and an electrode assembly 304. The electrode adaptor 302 is connected to the bottom of the compressible joint (204 in FIG. 2) and allows for replacement (interchange) of the electrode assembly 304. In one embodiment, the electrode adaptor 302 comprises three consecutive layers of material: (1) an inner conductive metal rod 306, (2) an electrically insulating tube 308 and (3) an outer conductive metal tube 310. The inner conductive metal rod 306 is threaded on the top such that it accepts the threads from the compressible joint 204 and threaded on the bottom such that it accepts the threads of the replaceable electrode assembly 304. The electrically insulating tube 308 has the same inner diameter as the inner conductive metal rod 306 and the same outer diameter as the outer conductive metal tube's inner diameter, and is either frictionally or adhesively bonded to both. The purpose of the electrically insulating tube 308 is to electrically separate an inner conductor 320 of the electrode assembly 304. In one embodiment, a first measurement cable 312 (coaxial cable) comprises an inner conductor coupled to the inner conductor 306 at location 314 and an outer conductor (shield) coupled to the outer conductive metal tube 310 at location 316.

The electrode assembly 304 comprises an electrode guard ring 318 and an electrode 320. The electrode 320 is referred to herein as the measurement electrode 320 to differentiate this electrode from the fixed electrode 108 located beneath the sample 116. The measurement electrode 320 is electrically connected to the inner conductor of the cable 312 via the inner conductor 306 of the adapter 302. The electrode guard ring 318 is electrically connected to the outer conductive metal tube 310 and the outer conductor of the cable 312.

It is common practice for those skilled in the art of parallel plate capacitance measurements to surround an inner measurement electrode 320, having some electrical potential not equal to ground, with a conductive ring guard ring 318 of a potential equal to ground. Such a structure minimizes fringing electrical fields that could alter the effective area of the electrodes, thus making the area (A) in Equation 1 unknown or inaccurate. Electrode assemblies 304 of various sizes and shapes (e.g., areas) can be interchangeably utilized to accommodate various sample types, sizes, shapes, and the like.

Whereas the preceding description references the top plate of a parallel plate capacitance measurement system, the following description refers to the bottom plate that is located beneath the sample 116. The fixed electrode 108 is composed of a conductive material (e.g., aluminum) and is connected to the plate electrode measurement cable 322 (coaxial cable) at point 324. The electrode 108 is electrically isolated from a metal table surface 118 by an electrically insulating material 120. The table 118 is connected electrically to an outer conductor (shield) of the cable 322 at point 226 for the purpose of shielding the measurements from ambient electrical noise, a practice common to those experienced in the art.

To perform a capacitance measurement, the impedance analyzer (104 of FIG. 1), which, in this embodiment is of the auto balancing bridge type, supplies an oscillating voltage to the inner electrode 320. In one embodiment, the frequency of the oscillating voltage is 1 MHz; however, other fixed, variable or swept frequencies may be used. The selection of the frequency is considered a design choice. Multiple discrete frequencies or a swept frequency may be used to provide impedance versus a frequency spectrum.

The applied oscillating voltage causes a current to flow through the sample 116 and through a resistor, located within the analyzer, placed in series with the sample 116. The impedance analyzer makes small adjustments to an internal current-voltage amplifier as to maintain a zero volt potential on the fixed electrode 108. By measuring the voltage at both the measurement electrode 320 and the voltage across the resistor in series with the sample 116, the sample impedance is calculated. In one embodiment, the imaginary part of the complex form of the impedance, the Reactance (X), is then converted to a capacitance at the oscillating voltage frequency (f) via Equation 2.

$$C = \frac{1}{2 π fX} \qquad ( 2 )$$

FIG. 4 depicts a cross-sectional representation of an inductance-based impedance sensor 400 that may be used as a portion of the apparatus of FIG. 1 in accordance with at least one embodiment of the invention. As in the case of a capacitance-based sensor (300 of FIG. 3), the inductance-based sensor 400 is coupled to the force-feedback sensor 204 via some form of coupler, e.g., a threaded stud. In one embodiment, the inductance-based sensor 400 comprises a coil 402 having a plurality of turns of wire surrounding a ferromagnetic core 404. The core is, for example, iron, to enhance the magnetic field created by the coil 402. Other ferrous or non-ferrous materials may be used. The coil 402, for example, is formed of a plurality of turns of bell wire surrounding the core 402. Each end of the wire comprising the coil 402 is electrically connected to separate electrically conductive connector 406. The connectors 406 may be, for example, threaded rods. The coil 402 is encased in an insulating hardened epoxy casing 408 such that a length of each connector 406 (not specifically shown) extend outside the casing 408. A female threaded coupler, that accepts the threads of the threaded stud 212, is affixed to the top center of the epoxy casing 408. The threaded stud 212 allows the inductance-based sensor 400 to be mechanically connected to the Z-axis actuator (114 in FIG. 1). The inductance-based sensor 400 is electrically connected to the impedance analyzer 104 in FIG. 1 via a pair of measurement cables 410. The inner conductors of the cables 410 are connected to the coil 402 via the connectors 406. The shield conductors of the measurement cables 410 are connected to one another (conductor 412) as close as possible to the inductance-based sensor 400.

When the impedance analyzer (104 of FIG. 1) provides an oscillating voltage to the coil of the inductance-based sensor 400, a changing magnetic field is produced. This changing magnetic field induces eddy currents in a conductive sample 116, which in-turn produce their own magnetic fields that alter the impedance of the inductance-based sensor 400. The impedance analyzer measures this impedance. In one embodiment, the imaginary part of the complex form of the impedance, the Reactance (X), is then converted to an inductance (L) at the oscillating voltage frequency (f) via Equation 3.

$$L = \frac{X}{2 π f} \qquad ( 3 )$$

In other embodiments of the invention, the capacitance-based sensor 300 may be driven with a DC voltage. A current flowing between the measurement electrode and the fixed electrode can be measured to determine the resistance of the sample. In still further embodiments, either the capacitance-based sensor 300 or the inductance-based sensor 400 may be used to apply radio frequency signals to the sample. In such an embodiment, the measurement electrode and/or the coil forms an antenna for coupling the radiofrequency signals to the sample as well as measuring a reflection of those signals. The reflected signals are indicative of sample's electrical and/or structural characteristics and can be used to determine sample impedance.

Using any of the embodiments of the impedance sensor, after an impedance measurement has been completed at a measurement location (e.g., one location of a plurality of locations defining the scan), the data is coupled (transmitted) from the impedance analyzer to the controller (or another computer) and recorded into a file. In one embodiment, the data is stored in ASCII format, having recorded an identifier of the measurement location, the travel of the vertical axis (if desired), and either the capacitance or inductance value recorded at that location for the particular frequency or each frequency used in a frequency sweep. As the planar measurement of a sample progresses, the controller reconstructs a two dimensional display of the collected data with respect to its location on the sample. An interpolation method can be applied to the data to approximate the data between measurement points, providing a visually smoother tomography representation of the data. The measurement data can then be recorded into a database, allowing for the quick sorting, retrieval, and analysis of the data at a future time.

The apparatus 100 may be operated in two modes: a contact mode (FIG. 5) and a non-contact (hovering) mode (FIG. 6). In the contact mode, the sensor is lowered at each measurement location to contact the sample 116. The force feedback sensor (202 of FIG. 2) is used to determine and control the amount of force applied between the sensor 206 and the sample 116 during measurement.

As shown in. FIG. 6, if the sensor 206 is not contacting the surface during a capacitance measurement the air gap 600 between the sample 116 and the sensor 206 is measured and accounted for in any calculations of the dielectric constant. Contacting the sensor 206 to the sample surface and then backing off the Z-axis actuator (114 of FIG. 1), creates a controlled distance defining the size of the air gap 600. Similarly, an inductance measurement is affected by the separation of the inductance-based sensor (400 of FIG. 4) and the conducting sample surface. However, if a uniform air gap is maintained across the entire sample surface, then this value is normalized out in a visual representation of the data.

Non-contact measurements are best suited for samples that are relatively flat with a uniform thickness. For samples that have non-uniform surface topography, it may be advantageous to perform a contact measurement at a plurality of locations on the sample. In this case, a sample thickness is simultaneously determined by measuring the vertical position of the MHU and comparing the position to the vertical position of the bottom electrode or table top in the event of a capacitance or inductance measurement, respectively. Before traversing to the next location, the MHU must raise vertically such that it does not drag across the surface of the sample during lateral movement. Upon reaching the next measurement location, the MHU is lowered until the operator (or software)-defined contact load is reached. This “hopping” motion between measurement points takes a considerably longer amount of time to complete than the non-contact “hovering” mode. Thus, using the non-contact mode, increases sampling throughput or measurement spatial resolution.

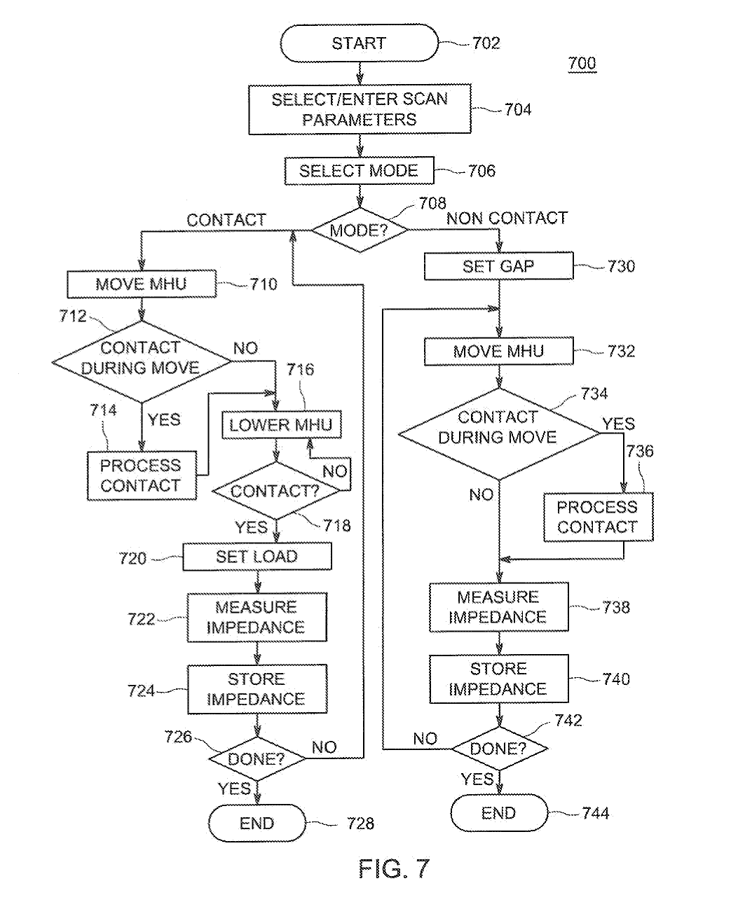

FIG. 7 depicts a flow diagram representing a method 700 of operation for the apparatus of FIG. 1 in accordance with at least one embodiment of the invention. The method 700 begins at step 702 and proceeds to step 704 wherein the scan parameters are either selected from a database or entered by the user. These scan parameters to find the locations at which the impedance will be measured as well as the type of sensor to be used. At step 706, the software or user selects a mode of operation—either contact or noncontact. At step 708, the method 700 queries which mode is to be used.

If contact mode is to be used, the method 700 proceeds to step 710 wherein the actuator assembly moves the MHU toward a location defined in the scan parameters. Some samples may contain areas of dramatic topographic irregularity. This would provide for a collision hazard for the traversing MHU. In one embodiment, the method 700 may detect and maneuver around these irregularities. As described above, the MHU contains a force-feedback sensor. In the case where the MHU is traversing across the sample at step 710 where there are no topographic irregularities, the force-feedback sensor should indicate zero load. During the move, the method 700 queries, at step 712, whether contact occurred. Such contact is detected when the load on the force feedback sensor exceeds a threshold, non-zero value. Although the contact force on the MHU is primarily lateral, the compressible joint articulates to distribute some of the contact force vertically to the force feedback sensor. The method registers this unexpected change in the load and compares it to an operator (or software)-defined threshold load value. Should this threshold be exceeded, the method 700, at step 714, sends a command to the actuator assembly to cease traversing and vertically raise the MHU in an effort to climb over the irregularity. At the point at which the force-feedback sensor registers a load below the threshold value, the method 700 commands the actuator assembly to continue traversing to the next measurement location. If again at some point the force-feedback sensor registers a load value that exceeds the threshold, the process (step 714) is repeated in an attempt to pass the MHU over top of the topographic feature on its way to the next measurement location.

If no contact is detected or the contact is resolved, the method 700 proceeds to step 716. At step 716, the method 700 lowers the MHU. At step 718 the method 700 queries whether the MHU has contacted the sample. Contact is detected when the load on the force feedback sensor exceeds a threshold. If contact is not detected, a method 700 continues to lower the MHU at step 716. Upon contact, the method 700 establishes a preset load between the sample and the sensor. Should the measurement location occur over the surface irregularity, the MHU will be lowered until the operator (or software)-defined load is reached, at which point an impedance measurement will be taken at step 722.

At step 724 the impedance value is stored in memory. The impedance value may be the reactance value, a capacitance value, a resistance value, or a inductance value, depending upon the type of sensor being utilized. At step 726, the method queries whether all the locations in the scan have been completed. If further locations are to be measured, the method 700 returns to step 710. If the scan is complete, the method 700 ends at step 728.

If, at step 708, the method 700 detects that the mode is the noncontact mode, the method 700 proceeds to step 730. At step 730, the method 700 sets the gap between the sensor and the sample. The gap is set by lowering the MHU until contacting the sample, then raising the MHU to a predefined distance above the sample. In other embodiments the gap may be set using other techniques.

At step 732, the method 700 moves the MHU in accordance with the scan parameters. In one embodiment, the method 700 may continuously move the MHU as impedance measurements are taken. In other embodiments, the method 700 may stop movement of the MHU at various locations to acquire an impedance measurement.

Steps to 734 and 736 operate in the same manner as steps 712 and 714 described above. These steps detect contact of the MHU with an irregular surface of the sample and process data contact as described above.

At step 738, the method 700 measures impedance values either continuously or discreetly as the MHU traverses the sample surface. At step 740, the method stores the impedance values acquired during step 738. The impedance value may be the reactance value, a capacitance value, a resistance value, or a inductance value, depending upon the type of sensor being utilized. At step 742, the method queries whether all the locations in the scan have been completed. If further locations are to be measured, the method 700 returns to step 732. If the scan is complete, the method 700 ends at step 744.

Various elements, devices, modules and circuits are described above in associated with their respective functions. These elements, devices, modules and circuits are considered means for performing their respective functions as described herein.

While the foregoing is directed to embodiments of the present invention, other and further embodiments of the invention may be devised without departing from the basic scope thereof, and the scope thereof is determined by the claims that follow.

1. Apparatus for determining planar impedance tomography of a sample comprising:
a measurement head unit comprising an impedance sensor;
a three-axis actuator assembly, coupled to the measurement head unit, for positioning the impedance sensor relative to a sample;
a controller, coupled to the three-axis actuator assembly, for controlling the three-axis actuator assembly to position the impedance sensor at a plurality of locations relative to the sample; and
an impedance analyzer, coupled to the impedance sensor, for determining an impedance value at each location in the plurality of locations.

2. The apparatus of claim 1 wherein the impedance sensor comprises at least one of a capacitance-based impedance sensor, inductance-based impedance sensor, resistance-based impedance sensor, or radio frequency-based impedance sensor.

3. The apparatus of claim 1 wherein the measurement head unit comprises a force feedback sensor for determining contact between the impedance sensor and the sample.

4. The apparatus of claim 1 wherein the controller defines a scan pattern identifying the plurality of locations.

5. The apparatus of claim 1 wherein the measurement head unit comprises a compressive joint enabling articulation of the impedance sensor relative to the three-axis actuator assembly.

6. The apparatus of claim 1 further comprising a fixed electrode positioned beneath the sample and wherein the impedance sensor comprises a measurement electrode, positioned above the sample, for measuring a capacitance of the sample located between the measurement electrode and the fixed electrode.

7. The apparatus of claim 6 wherein the impedance sensor further comprises an adapter, coupled between a compressive joint and the measurement electrode, for enabling various configurations of measurement electrodes to be used in the impedance sensor.

8. The apparatus of claim 6 wherein the impedance analyzer determines an impedance of the sample located between the measurement electrode and the fixed electrode.

9. The apparatus of claim 1 wherein the impedance sensor comprises a coil for measuring the inductance of the sample at each location.

10. The apparatus of claim 9 wherein impedance sensor further comprises a magnetic core around which the coil is wound.

11. The apparatus of claim 9 wherein the impedance analyzer determines an impedance of the sample located beneath the coil.

12. The apparatus of claim 1 wherein the impedance sensor is removably coupled within the measurement head unit and is interchangeable with at least one other impedance sensor.

13. A computer implemented method of measuring a planar impedance tomography of a sample comprising:
providing a scan defining a plurality of locations upon a sample;
positioning an impedance sensor at a first location in the plurality of locations;
measuring an impedance value using the impedance sensor at the first location;
storing the impedance value from the first location;
positioning the impedance sensor at least one additional location in the plurality of locations;
measuring an impedance value using the impedance sensor at the at least one additional locations; and
storing the impedance values from the at least one additional locations.

14. The method of claim 13 wherein each positioning comprises contacting the impedance sensor with a surface of the sample.

15. The method of claim 13 wherein each positioning comprises hovering the impedance sensor over a surface of the sample.

16. The method of claim 13 wherein each positioning comprises detecting inadvertent contact with the surface of the sample.

17. The method of claim 16 wherein, upon detecting inadvertent contact, maneuvering the impedance sensor to avoid contact and proceed to the first location or the at least one additional locations.

18. The method of claim 13 further comprising defining a mode wherein the impedance sensor at each location in a plurality of locations either contacts the sample or not contact the sample.

19. The method of claim 13 wherein the impedance sensor comprises at least one of a capacitance-based impedance sensor, inductance-based impedance sensor, resistance-based impedance sensor, or radio frequency-based impedance sensor.

20. The method of claim 13 further comprising creating a planar impedance tomography plotting the impedance values versus a plurality of locations.
